(19) United States
(12) Patent Application Publication
(10) Pub. No.: US 2008/0315725 A1
(43) Pub. Date: Dec. 25, 2008

(54) Force Generator

(75) Inventors: Peter Konstanzer, Taufkirchen (DE); Stefan Storm, Unterschleissheim (DE)

Correspondence Address: DARBY & DARBY P.C., P.O. BOX 770, Church Street Station, New York, NY, 10008-0770, US

(73) Assignee: Eurocopter Deutschland GmbH, Donauwoerth (DE)

(21) Appl. No.: 12/097,726

(22) PCT Filed: Dec. 1, 2006
(86) PCT No.: PCT/EP06/11569

§ 371 Date: Jun. 16, 2008

(30) Foreign Application Priority Data
Dec. 16, 2005 (DE) 10 2005 060 779.9

(51) Int. Cl. H01L 41/08

(52) U.S. Cl. 310/338

(57) ABSTRACT

A force generator is configured for attachment to a structure in order to controllably introduce vibrational forces into the structure in order to influence the vibration thereof. The force generator encompasses a flexural arm that is fastenable at least at one end to the structure; and an inertial mass that is coupled to the flexural arm remotely from the fastening end of the flexural arm; the flexural arm being equipped with at least one electromagnetic transducer, and a driving system being provided for the transducer, which system is set up such that by driving the transducer, it warps the flexural arm with the inertial mass and the transducer, and thereby displaces the inertial mass, in such a way that vibrational forces of variable amplitude, phase, and frequency are introducible into the structure.

### CROSS REFERENCE TO PRIOR APPLICATIONS

This application is a U.S. National Phase application under 35 U.S.C. § 371 of International Application No. PCT/EP2006/011569, filed on Dec. 1, 2006 and claims benefit to German Patent Application No. DE 10 2005 060 779.9, filed on Dec. 16, 2005. The International Application was published in German on Jul. 5, 2007 as WO 2007/073820 under PCT Article 21 (2).

The present invention relates to a force generator and to a method for operating the force generator. The force generator serves in particular to influence the vibration of structures, counter-vibrations being deliberately introduced into a structure in order to reduce the overall vibration level in the structure. The invention further relates to an apparatus for influencing vibration. The invention is applicable in particular to vibration control in helicopters and aircraft.

### BACKGROUND

Force generators serve to generate a desired force by means of a predetermined inertial mass. The forces always result in this context from the inertia of the inertial mass, moved in whatever fashion. In order to generate the greatest possible force, on the one hand the inertial mass can be moved with a maximum possible acceleration (or displacement). Alternatively or in addition thereto, a large force of this kind can also be generated by way of an inertial mass that is as large as possible.

Force generators based on the electrodynamic principle, in which the interaction between two moving electric charges is utilized, are already known. For this, an electrical conductor wound into a coil and provided with a current pulse is immersed in a magnetic field. The charges in the conductor thereupon experience a force impulse, with the result that the coil is caused to move. One disadvantage in this context is that the coil possesses a large mass, and can generate only relatively small accelerations and therefore small forces. The ratio between mass used and force generated is relatively high. In addition, an unfavorable energy balance exists with electrodynamic principles because of the ohmic resistance of the coil.

Force generators of this kind are used, for example, for controlled introduction of forces into vibrating structures (e.g. aircraft, motor vehicles, or machine components), in order to counteract high vibration levels and cancel them out. Problems occur in this context especially when the frequency of the structure to be regulated varies to a greater or lesser extent, as is the case, for example, in different operating states of the vibrating structure. Different operating states of this kind occur, for example, in aircraft in the different phases of flight, in particular on takeoff and on landing. With the known arrangements, vibration usually can be reduced only in a very narrow frequency range, which for many applications is disadvantageous.

### SUMMARY OF THE INVENTION

An object of the present invention is to provide a force generator that, with a predefined inertial mass, generates large accelerations and therefore forces, and at the same time has a favorable ratio between the inertial mass and the force generated therewith. The force generator according to the present invention is further intended to exhibit high quality, i.e. to have low self-damping and a low energy consumption. A further object is to provide a force generator that is universally and variably usable, i.e. with which, in particular, vibrations can be effectively reduced over the widest possible frequency range. A further object is that of providing a method with which such a force generator can be operated.

The present invention provides a force generator as described herein.

The force generator according to one aspect of the present invention is configured for attachment to a structure in order to controllably introduce vibrational forces into the structure in order to influence the vibration thereof, and encompasses a flexural arm that is fastenable at least at its one end to the structure, as well as an inertial mass that is coupled to the flexural arm remotely from the fastening end of the flexural arm. The flexural arm is equipped with an electromagnetic transducer, and a driving system is provided for the electromagnetic transducer, which system is set up such that by driving the electromagnetic transducer, it warps the flexural arm with the inertial mass and the transducer, and thereby displaces the inertial mass, in such a way that vibrational forces of variable amplitude, phase, and frequency can be generated in the structure, and are introducible via the fastening end into the structure.

It is particularly advantageous in this context that the driving system is set up to cause the inertial mass, the flexural arm, and the electromagnetic transducer to vibrate at adjustable amplitude, phase, and frequency. Different vibrational forces can thereby be deliberately generated, in particular over a wide frequency range, and introduced into a structure that is to be influenced. It is possible in this context either to excite the inertial mass and the flexural arm including the transducer less strongly, so that a lower vibration amplitude and thus a lower acceleration and lower force are achieved, or else to excite them strongly, so that a high vibration amplitude and thus a large acceleration and large force are achieved. In addition to adaptation of the vibration amplitude, the phase as well as the frequency are also variably adjustable.

A further advantage of the present invention is that the electromagnetic transducer can also be driven in such a way that introduction of vibrational forces at two or more frequencies simultaneously is possible. Driving occurs here at multiple frequencies or over a predetermined frequency range.

If the force generator is operated at resonant frequency (or in the vicinity of its resonant frequency/ies), the dynamic exaggeration of the displacement of the inertial mass can thereby advantageously be utilized in order to generate particularly large forces. Excitation in the region of the resonant frequency allows a large vibration amplitude for the inertial mass to be achieved for a predetermined inertial mass. This is accompanied by high acceleration, so that relatively large forces can be generated by the inertial mass.

Usefully, the inertial mass constitutes a multiple of the mass of the flexural arm including the transducer, so that force generator possesses a relatively small total mass and achieves high efficiency.

The transducer is preferably a piezoelectric actuator. An actuator of this kind possesses a very rapid response characteristic and can be precisely regulated in terms of both its displacement travel amplitudes and its frequencies. Accurately predetermined excitation frequencies can thus be established for the force generator. A piezoelectric actuator operates with long displacement travels and high resolution even with large counterforces, so that vibrational forces can be reliably generated even with a large inertial mass.

Particularly preferably, the piezoelectric actuator is a stacked piezoelement (i.e. a so-called “piezostack”) having a d33 effect. With the d33 effect, which as is known is also referred to as a longitudinal effect, the change in the length of the piezoelectric element occurs in the direction of the applied electric field, i.e. along the stack direction or longitudinal direction of the piezoelement. The change in length produced in this context is known to be greater than the change in length in the context of the d31 effect, in which the change in length occurs transversely to the direction of the applied electric field.

According to a preferred embodiment, the transducer is drivable in such a way that it effects a change in length in the longitudinal direction of the flexural arm. This results in a warping of the flexural arm, with the result that in turn the inertial mass is displaced, so that vibrations of the flexural arm with the inertial mass and the transducer are triggered in order to generate corresponding vibrational forces. If the transducer is arranged parallel to a neutral ply that extends, in the context of a symmetrically constructed flexural arm, along the center line of the flexural arm, the length of a ply provided parallel to the neutral ply can thus be changed as compared with the neutral ply. The ply having the greater length induces a deflection in the direction toward the ply having the shorter length. If the change in length is repeated at periodic intervals, the result is a flexural vibration of the flexural arm including the transducer and the inertial mass. With an excitation in the resonant frequency range, the system oscillates to large amplitudes.

Particularly preferably, at least one transducer is arranged respectively on mutually oppositely located sides of the neutral ply, so that a deflection to both mutually oppositely located sides of the neutral ply is generated, with the result that, advantageously, the displacement of the inertial mass can be increased.

Preferably, the transducer is non-positively and/or positively connected to the neutral ply. This on the one hand ensures that the transducer is positioned in stationary fashion and can effect an accurately repeatable warping of the flexural arm. On the other hand, because the transducer is positioned in the vicinity of the neutral ply, the transducer is deflected relatively little at very high vibration amplitudes. This is a feature to protect the transducer from mechanical deformation resulting from bending. The protection can be enhanced if the at least one transducer is arranged inside the flexural arm or embedded thereinto. Damage to a mechanically sensitive transducer from outside is thus possible only with difficulty. In addition, an encapsulation of the transducer can be achieved by arranging the transducer inside the flexural arm, so that the force generator is also usable, for example, in a wet or chemically aggressive environment.

According to a further preferred embodiment of the invention, a spacing element is arranged between the inertial mass and one end of the transducer. The spacing element allows the transducer to be positioned even more securely in its location. The spacing element preferably has a low density, in order to increase the ratio between the inertial mass and the mass of the flexural arm including the transducer. In particular, the resonant frequency of the assembly made up of the flexural arm, transducer, and inertial mass can be deliberately influenced by appropriate selection of the material for the spacing element.

In addition, a protective outer ply of the flexural arm, which ply is arranged at a lateral distance from the neutral ply, can be non-positively and/or positively connected to the transducer. The use of an outer ply results in a layered design for the flexural arm, and thus provides simple protection from external influences on the transducer. Non-positive connection, for example by adhesive bonding, and positive connection, for example by bolting, ensure accurate positioning of the parts with respect to one another.

Particularly preferably, the flexural arm is embodied as a fiber composite design with an integrated transducer. The flexural arm is manufactured in layered fashion using fiber composite materials, in particular glass fiber-reinforced (GFR) plastic, the layered construction being, in a last working step, infiltrated or injected with a resin system e.g. by means of a known resin transfer molding (RTM) method, and then cured. A particularly long service life for the force generator may be achieved by way of a fiber composite design of this kind.

The transducer is preferably under a compressive preload. The result of this is that even with a high vibration amplitude (e.g. with resonance exaggeration) of the flexural arm, it is always compressive forces, and not tensile forces that are hazardous to the transducer, that act on the transducer. This is of particular importance for a transducer that comprises piezoceramic layers. The transducer that is under compressive preload on the transducer can better withstand large vibration amplitudes. The compressive preload can be impressed mechanically. The transducer can, however, also be thermally preloaded. This can be achieved, for example, by introducing it into a matrix that possesses a coefficient of thermal expansion different from that of the transducer. A compressive preload can then be achieved upon thermal curing of the matrix. Another possibility is to apply an electrical offset voltage to the transducer. The transducer is thus always exposed to compression, and is protected from tensile loading even at large vibration amplitudes.

The force generator according to the present invention typically has a length of 3 to 60 centimeters. With suitable dimensioning of all the components, the inertial mass can then have imparted to it a vibration that exhibits a maximum vibration amplitude in the range from 0.1 to 3 centimeters.

Another aspect of the present invention is provided as a method for operating the force generator as described above, such that by suitable driving of the electromagnetic transducer, the flexural arm with the inertial mass and the transducer is warped, and the inertial mass thereby displaced, in such a way that vibrational forces of variable amplitude, phase, and frequency are generated.

Another aspect of the present invention is an apparatus for influencing vibration that is embodied for attachment to at least one structure in order to controllably introduce vibrational forces into the structure, two force generators of the kind described above being arranged in such a way that the flexural arm of the first force generator is arranged along the extension of the flexural arm of the second force generator.

The force generator according to the present invention can thus also be used in a symmetrical design, two individual force generators of the above-described kind being used in such a way that they are each fastened, not with the ends of the flexural arms coupled to the inertial mass, to a structure to be influenced in terms of vibration, or are connected to one another in such a way that they form a flexural arm having inertial masses arranged on either side, i.e. at both ends of a flexural arm. The inertial masses should have the same offset from the structure, i.e. the lever arms of the flexural arms are preferably identical. The arrangement can be driven in such a way that the inertial masses are displaced in parallel fashion, i.e. in the same direction, or in antiparallel fashion, i.e. in opposite directions. In the latter case, not only forces but also moments can be introduced into the structure.

A further symmetrical use of the force generator according to the present invention is the arrangement, hereinafter also referred to as a “swing oscillator,” in which the flexural arm of a first force generator is lengthened, so to speak, out beyond the inertial mass, and the free end of the lengthened flexural arm is likewise attached to the structure but at a different point. In other words, a flexural arm is provided whose opposite ends are fastenable to a structure, at least one inertial mass being provided at the center of the flexural arm. With an arrangement of this kind, the introduction of forces occurs in moment-free fashion.

The force generator according to the present invention, and its symmetrical application, are used in particular for active vibration control of structures (aircraft, motor vehicles, machine components, etc.).

### BRIEF DESCRIPTION OF THE DRAWINGS

Further features and advantages of the invention are evident from the description below of various exemplifying embodiments according to the present invention in conjunction with the accompanying drawings, in which:

FIG. 1 schematically depicts a first embodiment of the force generator according to the present invention in a rest position;

FIG. 2 schematically depicts the first embodiment of the force generator of FIG. 1 in a deflected position;

FIG. 3 schematically depicts a second embodiment of the force generator according to the present invention in a rest position;

FIG. 4 schematically depicts the second embodiment of the force generator of FIG. 3 in a deflected position;

FIG. 5 schematically depicts a third embodiment of the force generator according to the present invention in a rest position;

FIG. 6 schematically depicts the third embodiment of the force generator of FIG. 5 in a deflected position;

FIG. 7 schematically depicts a fourth embodiment of the force generator according to the present invention in a rest position; and

FIG. 8 schematically depicts a further embodiment according to the present invention that encompasses two symmetrically arranged force generators; and

FIG. 9 shows a symmetrical arrangement, alternative to FIG. 8, of two force generators.

### DETAILED DESCRIPTION

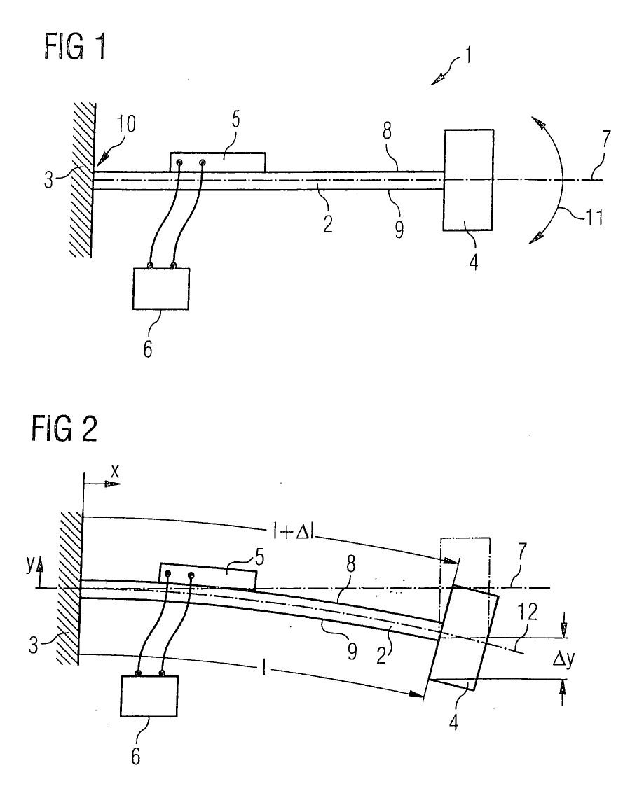

FIG. 1 schematically depicts a first embodiment of force generator 1 according to the present invention. It comprises a flexural arm 2 that is attached at one end 10 to a structure 3, and comprises an inertial mass 4 at the other end. Structure 3 is, for example, an aircraft, a motor vehicle, a machine component, or any other component; structure 3 vibrates in an undesired fashion. To reduce these vibrations, force generator 1 is connected to structure 3 so that counter-vibrations can be deliberately introduced into structure 3 in order to reduce the overall level of the vibrations in structure 3, as explained below in greater detail.

Mounted on flexural arm 2 is an electromagnetic transducer 5, in particular a piezoelectric actuator, that is electrically connected to a driving system 6. The position of driving system 6 is arranged at a distance from flexural arm 2 and from transducer 5 such that it does not impede the movement of flexural arm 2 including transducer 5 and inertial mass 4. In the position depicted in FIG. 1, flexural arm 2, together with inertial mass 4 and electromagnetic transducer 5, is located in a rest position such that center line 7 of flexural arm 2 extends horizontally.

Electromagnetic transducer 5 is driven in such a way that it experiences a positive change in length Δl in the longitudinal direction of flexural arm 2. Transducer 5 is connected to upper edge fiber 8 of flexural arm 2 in such a way that change in length Δl of transducer 5 is transferred into upper edge fiber 8 so that its length 1 is extended by an amount Δl. Because no change in length is exerted on lower edge fiber 9, a length difference of Δl is therefore produced between upper edge fiber 8 and lower edge fiber 9. As is evident from FIG. 2, this length difference Δl leads to a warping of flexural arm 2 in the negative y direction. Inertial mass 4, connected rigidly to flexural arm 2, is shifted in this context, by an amount Δy, from its rest position depicted with a dashed line into a deflected position depicted by a solid line. As a consequence of the length increase, by an amount Δl, of upper edge fiber 8, center line 7 of flexural arm 2 thus changes its horizontal orientation into the deflected position depicted by the dot-dash line 12. As a result of an at least non-positive connection between transducer 5 and flexural arm 2, transducer 5 follows the curvature of upper edge fiber 8.

By appropriate driving of transducer 5, flexural arm 2 including transducer 5 and inertial mass 4 can consequently be excited to vibrate, such that inertial mass 4 and flexural arm 2 with transducer 5 vibrate up and down about center line 7 extending horizontally, as indicated by arrow 11 in FIG. 1. The amplitude, phase, and frequency of the vibration are adjustable by suitable driving (e.g. U(ω) or U (Δω)) of transducer 5, so that vibrational forces are deliberately introducible via attachment point 10 into structure 3 in order to bring about, by superposition of introduced vibrations and structural vibrations, a reduction, ideally a cancellation, of the vibrations over a wide frequency range and/or at multiple frequencies simultaneously. To regulate the driving system, at least one sensor is provided which senses the vibrations of structure 3 in order to regulate driving system 6 on the basis of the acquired sensor signals.

If transducer 5 is driven, or the change in length Δl is accomplished, at a frequency that is in the region of the resonant frequency of the system made up of flexural arm 2, inertial mass 4, and transducer 5, inertial mass 4 can be displaced in the y direction by an amount that, as a result of resonance exaggeration, is several times greater than the amount Δy. Inertial mass 4 experiences a greater acceleration as a result of the greater vibration amplitude, so that substantially larger forces or greater vibration amplitudes are generated.

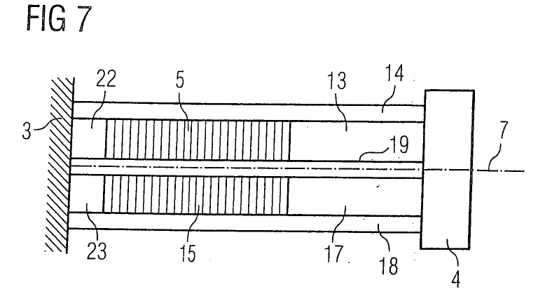

In the embodiment depicted in FIGS. 1 and 2, electromagnetic transducer 5 is preferably a stacked piezoelement having a d33 effect. The stack direction extends substantially in the longitudinal direction of flexural arm 2, i.e. in a horizontal direction, in order to bring about the above-described change in length Δl in the longitudinal direction of flexural arm 2. Transducer 5 is non-positively connected to flexural arm 2, e.g. by adhesive bonding. Alternatively, a recess can be provided in flexural arm 2, into which recess transducer 5 is fitted in such a way that horizontal shifting or sliding of transducer 5 is not possible. To protect transducer 5, the arrangement of flexural arm 2 and transducer 5 can additionally be equipped with a protective layer or embedded into a fiber composite material arrangement, the latter being explained in additional detail in connection with the description of FIG. 7.

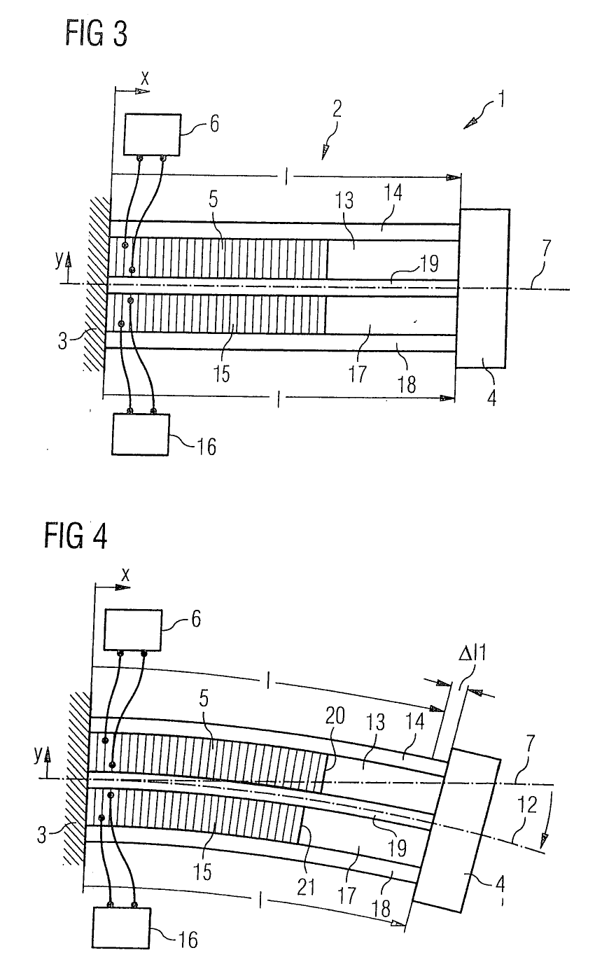

FIG. 3 depicts a second embodiment of the force generator according to the invention. Flexural arm 2 is constructed in a layered design. It has a neutral ply 19 that extends along center line 7 of flexural arm 2. Parallel thereto, flexural arm 2 has an upper outer ply 14 and a lower outer ply 18. Arranged between upper outer ply 14 and neutral ply 19 are a first actuator constituting electromagnetic transducer 5, and an additional element 13 that is hereinafter also referred to as a spacing element, which occupies the distance between actuator 5 and inertial mass 4 as well as the distance between neutral ply 19 and upper outer ply 14. A second actuator 15, and a spacing element 17 adjoining it, are located in the same fashion between neutral ply 19 and lower outer ply 18. First actuator 5 is coupled to a driving system 6, and second actuator 15 to a driving system 16, which systems are respectively regulated as a function of sensor signals that are received from corresponding sensors for sensing the vibration of structure 3. The driving signals for driving systems 6, 16 can be identical or different (e.g. U(ω₁) and U(ω₂)); each individual transducer 5, 15, can also be excited simultaneously at multiple frequencies.

In the embodiment depicted in FIG. 3, transducers 5, 15 are once again embodied as piezoelectric actuators, in particular as stacked piezoelements having a d33 effect. The stacking or longitudinal direction of the piezoelement extends horizontally, so that upon application of an electric field in the stacking direction of piezoelement 5, a change in length occurs in the longitudinal direction of flexural arm 2. The rest position of force generator 1, as depicted in FIG. 3, can be shifted into a deflected position by driving first piezoelectric actuator 5. If first actuator 5 experiences a change in length Δl1 (cf. front end 20 of first actuator 5), this change in length Al1 is transferred, because of the coupling with spacing element 13 and with upper outer ply 13, to inertial mass 4. At the same time, second actuator 15 arranged parallel thereto experiences no change in length (cf. front end 21 of second actuator 15), so that the length of lower outer ply 18 is not modified. As in the case of the first embodiment depicted in FIG. 2, the flexural arm is in this fashion warped in the negative y direction (see FIG. 4). The function and the manner of operation of force generator 1 are otherwise analogous to those of the first embodiment.

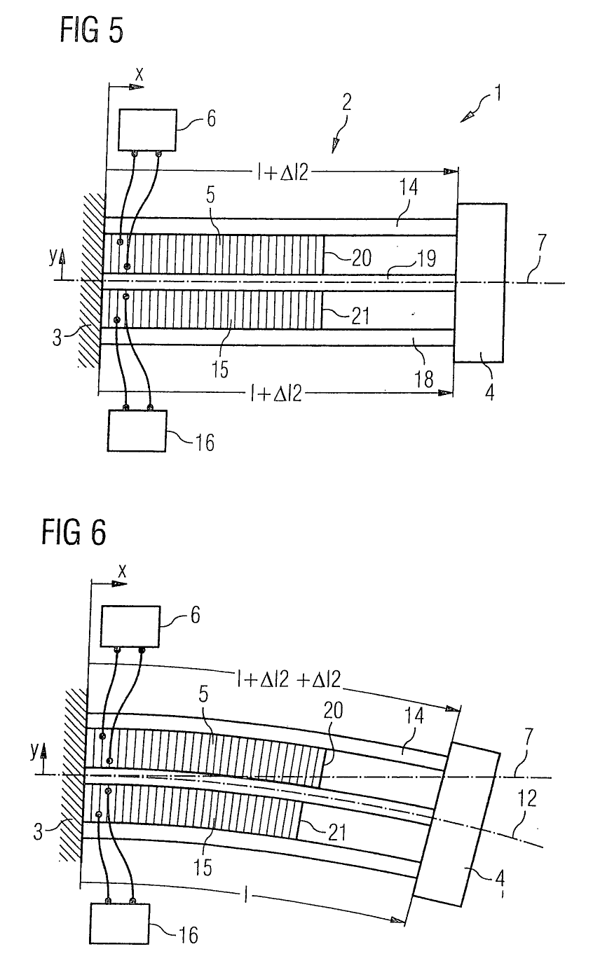

Even more efficient vibration of inertial mass 4 is achieved with the inertial force generator 1 depicted in FIGS. 5 and 6. This third embodiment is largely identical to the second embodiment. One difference is that already in the rest position of flexural arm 2, both transducers 5, 15 are driven so that they are displaced by an amount equal to a change in length Δl2, i.e. a preload is applied to transducers 5, 15. First actuator 5 is then lengthened by an additional change in length Δl2, while second actuator 15 is shortened by that change in length Δl2 (see FIG. 6). The first actuator therefore effects a change in length equal to Δl2+Δl2, while the second actuator exhibits no further change in length. This design takes into account the circumstance that starting from its baseline length at which no electric field is applied, a piezoceramic material can only be lengthened.

FIG. 7 depicts a particularly preferred embodiment of the invention. Flexural arm 2 is embodied as a fiber composite design. Neutral ply 19 and outer plies 14, 18 are made of fiber composite material, in particular of glass fiber-reinforced (GFR) plastic. Spacing elements 13, 22 and 17, 23 arranged respectively on either side of transducers 5, 15 can be made of fiber composite materials, other lightweight materials (e.g. foamed material), or metal. In the manufacture of flexural arm 2, firstly transducers 5, 15 are mounted on either side of neutral ply 19, if applicable by immobilization by adhesive bonding. The regions on the sides of transducers 5, 15 are then filled up with corresponding spacing elements 13, 22 and 18, 23, respectively, which can be made up of multiple fiber composite material plies. Outer plies 14, 18 are put in place to protect piezoelectric actuators 5, 15, and lastly the layered fiber composite material arrangement is injected in known fashion with a resin system and cured, if applicable with the application of heat, typically by means of a known resin injection method such as, for example, the RTM method. Outer plies 14 and 18 protect the sensitive piezoceramic materials of actuators 5, 15 from moisture and from the penetration of foreign objects. By appropriate selection of the materials of spacing elements 13, 17, 22, and 23, the resonant frequency of flexural arm 2 with transducers 5, 15 and inertial mass 4 can be set to a desired value. A particularly lightweight arrangement, in which the mass of flexural arm 2 with transducers 5, 15 is much less than inertial mass 4, can also be created by suitable selection of materials.

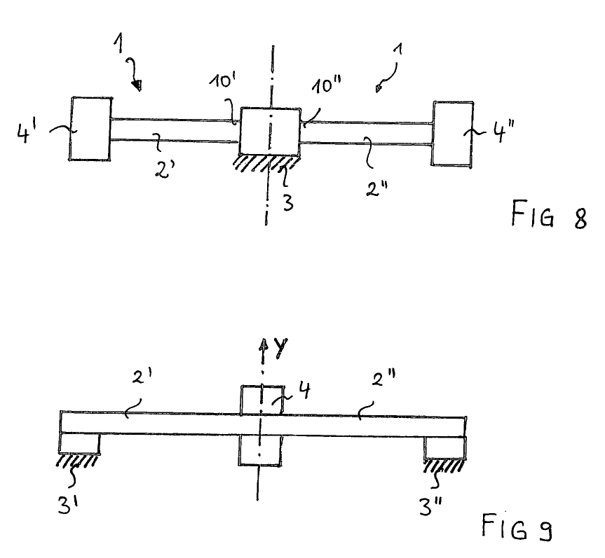

The force generator described above can also be used in a symmetrical arrangement in order to create an apparatus for influencing vibration. FIG. 8 schematically depicts a first embodiment having two force generators, the flexural arms of the two force generators being arranged along one another's extensions. As is apparent from FIG. 8, flexural arms 2′, 2″ of the respective force generators 1 are arranged in such a way, on structure 3 that is to be influenced in terms of vibration, that inertial masses 4′, 4″ are at identical distances from the respective attachment points 10′ and 10″. Flexural arms 2, 2″ are preferably embodied integrally, so that the apparatus for influencing vibration substantially comprises one flexural arm at whose outer ends the respective inertial masses 4′ and 4″ are arranged. The integral flexural arm is then preferably arranged at the center on structure 3. The arrangement depicted in FIG. 8 can be driven, by transducers arranged on flexural arms 2, 2″, in such a way that inertial masses 4′, 4″ are displaced in either parallel fashion, i.e. in the same direction (e.g. in the positive y direction), or in anti-parallel fashion, i.e. in opposite directions. In the case of a parallel displacement of inertial masses 4′, 4″, forces as well as moments can be introduced into structure 3. With an anti-parallel displacement, force is introduced into structure 3 in moment-free fashion.

FIG. 9 depicts a further symmetrical arrangement of force generators according to the present invention that shows a so-called “swing oscillator” arrangement. Looking at the left portion of FIG. 9, this depicts a force generator as described in conjunction with FIGS. 1 to 7, except that flexural arm 2′ is, so to speak, lengthened by inertial mass 4, i.e. to the right in FIG. 9, the lengthened end being attached to a further structure 3″ or to another point 3″ on the structure. In other words, the arrangement according to FIG. 9 substantially encompasses a flexural arm whose outer ends, i.e. the left and the right end in FIG. 9, are attached at different points 3′ and 3″. Inertial mass 4 is arranged at the center of the flexural arm and is displaced, by analogy with the description above, in a direction perpendicular to the plane of the flexural arm, i.e. in a positive and negative y direction. This introduction of vibrational forces at points 3′ and 3″ occurs in moment-free fashion.

1-25. (canceled)

26. A force generator device configured for attachment to a structure to controllably induce vibrational forces into the structure to influence the vibration of the structure, comprising:
a flexural arm having a longitudinal axis, a lateral axis, a center line, and a length;
wherein the flexural arm has at least one electromagnetic transducer, a neutral ply extending along the center line, an outer ply disposed at a distance along the lateral axis of the flexural arm from the neutral ply, a first end, and a second end, wherein the first end is fastenable to the structure;
an inertial mass coupled to the flexural arm at the second end of the flexural arm;
a driving system configured to drive the at least one transducer so as to warp the flexural arm and wherein warping the flexural arm displaces the inertial mass so as to introduce vibrational forces of varying amplitude, phase and frequency into the structure;
a spacing element disposed between the inertial mass and the transducer; and,
wherein the outer ply is connected to at least one of the at least one transducer and the spacing element.

27. The force generator device as recited in claim 26, wherein the at least one transducer is drivable so as to introduce vibrational forces of at least two frequencies.

28. The force generator device as recited in claim 26, wherein the at least one transducer is drivable so as to vibrate the flexural arm with the inertial mass and the at least one transducer at a resonant frequency.

29. The force generator device as recited in claim 26, wherein the inertial mass constitutes a multiple of a mass of the flexural arm including the at least one transducer.

30. The force generator device as recited in claim 26, wherein the at least one transducer includes a piezoelectric actuator.

31. The force generator device as recited in claim 30, wherein the piezoelectric actuator is a stacked piezoelement having a d33 effect.

32. The force generator device as recited in claim 26, wherein the at least one transducer is drivable so as to change the length of the flexural arm in the longitudinal axis.

33. The force generator device as recited in claim 26, wherein the at least one transducer is disposed parallel to the neutral ply.

34. The force generator device as recited in claim 33, wherein the at least one transducer includes at least two transducers respectively arranged on mutually opposing sides of the neutral ply.

35. The force generator device as recited in claim 33, wherein the at least one transducer is connected to the neutral ply.

36. The force generator device as recited in claim 26, wherein the at least one transducer is disposed inside the flexural arm.

37. The force generator device as recited in claim 26, wherein the flexural arm includes a fiber composite and wherein the at least one transducer is integrated in the flexural arm.

38. The force generator device as recited in claim 26, wherein the at least one transducer is under a compressive preload.

39. The force generator device as recited in claim 38, wherein the compressive preload is impressed mechanically.

40. The force generator device as recited in claim 38, wherein the at least one transducer is thermally pretreated so as to provide the compressive preload.

41. The force generator device as recited in claim 26, wherein an electrical offset voltage is applied to the at least one transducer.

42. A method for operating a force generator comprising:
providing a flexural arm having a longitudinal axis, a lateral axis, a center line, a length, at least one electromagnetic transducer, a neutral ply extending along the center line, an outer ply disposed at distance along the lateral axis of the flexural arm from the neutral ply, a first end, a second end, wherein the first end is fastenable to the structure;
coupling an inertial mass to the flexural arm at the second end of the flexural arm;
disposing a spacing element between the inertial mass and the transducer;
connecting the outer ply to at least one of the at least one transducer and the spacing element; and,
driving the at least one transducer so as to warp the flexural arm with the inertial mass and the transducer and wherein warping the flexural arm displaces the flexural arm so as to produce vibrational forces of variable amplitude, phase, and frequency.

43. The method as recited in claim 42, wherein driving the at least one transducer is performed at multiple frequencies or over a predefined frequency range so as to introduce vibrational forces of at least two frequencies into the structure.

44. The force generator device as recited in claim 26, further comprising:
an auxiliary flexural arm having an auxiliary longitudinal axis, an auxiliary lateral axis, an auxiliary center line and an auxiliary length;
wherein the auxiliary flexural arm has at least one auxiliary electromagnetic transducer, an auxiliary neutral ply extending along the auxiliary center line, an auxiliary outer ply disposed at a distance along the auxiliary lateral axis of the auxiliary flexural arm from the auxiliary neutral ply,
an auxiliary first end and an auxiliary second end, wherein the auxiliary first end is fastenable to an auxiliary structure;
an auxiliary inertial mass coupled to the auxiliary flexural arm at the auxiliary second end of the auxiliary flexural arm;
an auxiliary driving system configured to drive the at least one auxiliary transducer so as to warp the auxiliary flexural arm and wherein warping the auxiliary flexural arm displaces the auxiliary flexural arm so as to introduce vibrational forces of varying amplitude, phase and frequency into the auxiliary structure;
an auxiliary spacing element disposed between the auxiliary inertial mass and the at least one auxiliary transducer;
wherein the auxiliary outer ply is connected to at least one of the at least one of the auxiliary transducer and the auxiliary spacing element; and,
wherein the auxiliary flexural arm is disposed in line with the flexural arm.

45. The force generator device as recited in claim 44, wherein the flexural arm with the inertial mass and the auxiliary flexural arm with the auxiliary inertial mass are disposed symmetrically with respect to each other.

46. The force generator device as recited in claim 44, wherein the flexural arm and the auxiliary flexural arm are structurally integral.

47. The force generator device as recited in claim 44, wherein the flexural arm and the auxiliary flexural arm are attached to the same structure.

48. The force generator device as described in claim 46, wherein the structure is disposed between the flexural arm and the auxiliary flexural arm.

49. The force generator device as described in claim 46, wherein the inertial mass and the auxiliary inertial mass are disposed between the structure and the auxiliary structure.
